(19) United States
(12) Patent Application Publication
(10) Pub. No.: US 2016/0149549 A1
(43) Pub. Date: May 26, 2016

(54) ALARM TONE ADJUSTMENT CIRCUIT AND ELECTRONIC DEVICE APPLYING THE CIRCUIT

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventor: LONG ZHAO, Wuhan (CN)

(21) Appl. No.: 14/585,396

(22) Filed: Dec. 30, 2014

(30) Foreign Application Priority Data
Nov. 21, 2014 (CN) 201410671287.0

(51) Int. Cl. H03G 3/32; G08B 3/10

(52) U.S. Cl. CPC H03G 3/32; G08B 3/10

(57) ABSTRACT

An alarm tone adjustment circuit includes a sound collection unit with a function of collecting sound of a surrounding environment, an analog-digital (A/D) convertor, and a processing unit. The A/D convertor transforms the sound of a surrounding environment from the sound collection unit to a digital signal. The processing unit is coupled to the A/D convertor and an alarm tone unit, and determines a decibel range of the sound of surrounding environment according to a duty cycle of the digital signal, and adjusts a volume of a ring output from the alarm tone unit according to the decibel range of the sound of surrounding environment. Therefore, the alarm tone of the electronic device can be changed effectively according to the sound of surrounding environment.

### FIELD

The subject matter herein generally relates to an alarm tone adjustment circuit and an electronic device applying the adjustment circuit.

### BACKGROUND

An alarm tone adjustment circuit is usually applied in a plurality of electronic devices, such as a mobile phone.

### BRIEF DESCRIPTION OF THE DRAWINGS

Implementations of the present technology will now be described, by way of example only, with reference to the attached figures.

FIG. 1 is a block diagram of an example embodiment of an alarm tone adjustment circuit.

FIG. 2 is a circuit diagram of an sound collection unit of FIG. 1.

FIG. 3 is a circuit diagram of an analog-digital convertor, a switch and buffer unit, and a processing unit of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently coupled or releasably coupled. The term “comprising,” when utilized, means “including, but not necessarily limited to”; it specifically indicates open-ended inclusion or membership in the so-described combination, group, series and the like.

The disclosure will now be described in relation to an alarm tone adjustment circuit.

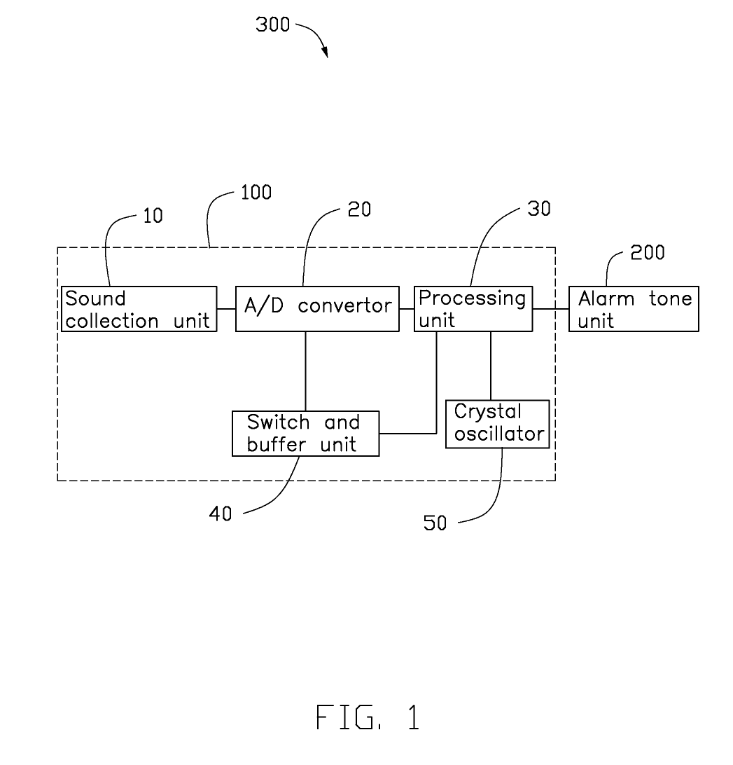

FIG. 1 illustrates a block diagram of an example embodiment of an alarm tone adjustment circuit 100 applied in an electronic device 300, such as mobile phone, tablet computer or notebook computer. In the embodiment, the electronic device 300 is a mobile phone. The alarm tone adjustment circuit 100 is set on a motherboard of the mobile phone, and is coupled to an alarm tone unit 200 of the motherboard of the mobile phone, for changing an alarm tone from the alarm tone unit according to a sound of a surrounding environment. The alarm tone adjustment circuit 100 includes a sound collection unit 10, an analog-digital (A/D) convertor 20, a processing unit 30, a switch and buffer unit 40, and a crystal oscillator 50.

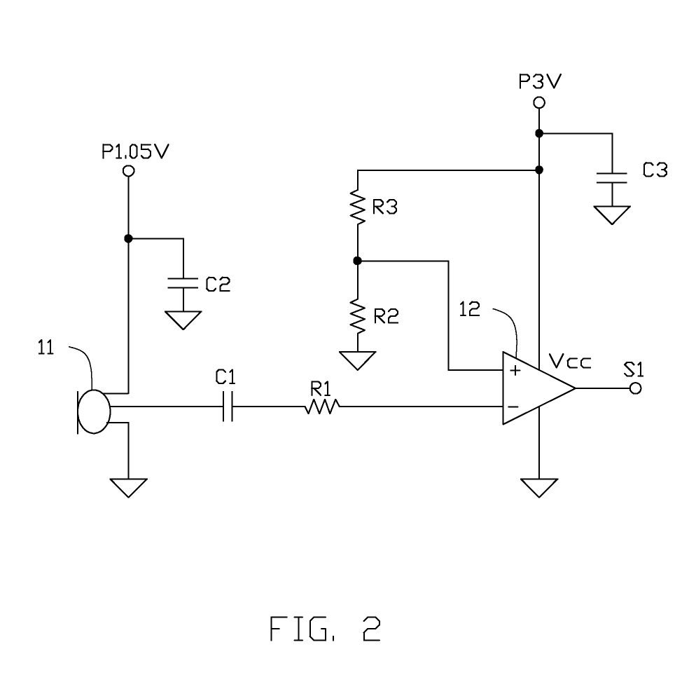

FIG. 2 illustrates a circuit diagram of the sound collection unit 10 of the alarm tone adjustment circuit 100. The sound collection unit 10 includes a sound sensor 11, an amplifier 12, capacitors C1, C2, C3, and resistors R1, R2, R3. A first terminal of the sound sensor 11 is coupled to a power source P1.05V, and is grounded through the capacitor C2. A second terminal of the sound sensor 11 is grounded. A third terminal of the sound sensor 11 is coupled to an inverting input terminal of the amplifier 12, through the capacitor C1 and the resistor R1. A non-inverting input terminal of the amplifier 12 is grounded through the resistor R2. The non-inverting input terminal of the amplifier 12 is also coupled to a power source P3V through the resistor R3. A non-inverting input terminal of the amplifier 12 is coupled to a node between the resistor R2 and the resistor R3. A power terminal Vcc of the amplifier 12 is coupled to the power source P3V, and is grounded through the capacitor C3. A ground terminal of the amplifier 12 is grounded. The sound collection unit 10 can collect the sound of a surrounding environment of the mobile phone, and output a smooth sound signal to the amplifier 12, through changing the sharp sound signal to the smooth sound signal, and filter out noise signals from a clock of a plurality of components of the sound collection unit 10. The amplifier 12 enlarges a voltage of the sound signal form the sound sensor 11 from 1.05 volts (Vs) to about 3 V, and outputs a sound signal S1.

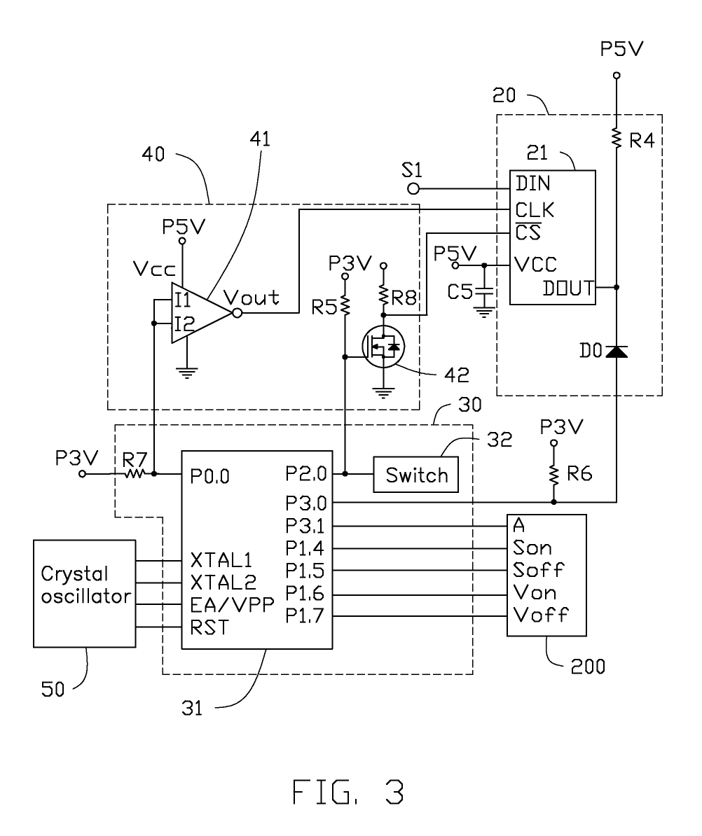

FIG. 3 illustrates a circuit diagram of the A/D convertor 20, the processing unit 30, and the switch and buffer unit 40. The A/D convertor 20 includes an A/D converting chip 21, a diode D0, and a resistor R4. A input pin DIN of the A/D converting chip 21 is coupled to an output terminal of the amplifier 12, for receiving the sound signal S1, and transforms the sound signal amplified S1 to a digital signal. A power pin Vcc of the A/D converting chip 21 is coupled to the power source P5V, and is grounded through a capacitor C5. An output pin DOUT of the A/D converting chip 21 is coupled to a power source P5V through the resistor R4. A cathode of the diode D0 is coupled the output pin DOUT. An anode of the diode D0 is coupled to the processing unit 30.

The processing unit 30 includes a processor 31, a switch 32, and a resistor R7. An input/output (I/O) port P2.0 of the processor 31 is coupled to the switch 32, and is coupled to the power source P3V through a resistor R5. An I/O port P3.0 of the processor 31 is coupled to the anode of the diode D0, and is coupled to the power source P3V through a resistor R6. An I/O port P3.1 of the processor 31 is coupled to a volume adjusting port A of the alarm tone unit 200. An I/O port P1.4 of the processor 31 is coupled to a vibration on port Son of the alarm tone unit 200. An I/O port P1.5 of the processor 31 is coupled to a vibration off port Soff of the alarm tone unit 200. An I/O port P1.6 of the processor 31 is coupled to a ringing on port Von of the alarm tone unit 200. An I/O port P1.7 of the processor 31 is coupled to a ringing off port Voff of the alarm tone unit 200. An I/O port P0.0 of the processor 31 is coupled to the power source P3V through the resistor R7. Clock pins XTAL1, XTAL2 of the processor 31, a reverse pin EA/VPP, and a reset pin RST are coupled to the crystal oscillator 50.

The switch and buffer unit 40 includes a buffer 41 and an electronic switch 42. Input terminals I1, I2 of the buffer 41 are coupled to the I/O port P0.0 of the processor 31. An output terminal of the buffer 41 is coupled to the clock pin CLK of the A/D converting chip 21. A power pin Vcc of the buffer 41 is coupled to the power source P5V. The buffer 41 receives a voltage signal from the I/O port P0.0 of the processor 31, and outputs a clock signal to the A/D converting chip 21. The electronic switch 42 is an n-channel metal oxide semiconductor field-effect transistor (MOSFET). A gate of the electronic switch 42 is coupled to the I/O port P2.0 of the processor 31. A source of the electronic switch 42 is grounded. A drain of the electronic switch 42 is coupled to the power source P5V through a resistor R8, and is coupled to the selection pin CS of the A/D converting chip 21.

In use, the alarm tone adjustment function can be turned on through operation interface of the mobile phone. When the alarm tone adjustment function is turned on, the switch 32 outputs a digital high level signal. The I/O port P2.0 of the processor 31 receives the digital high level signal from the switch 32, and the processor 31 starts operating. The electronic switch 42 is turned on. The drain of the electronic switch 42 outputs a digital low level signal to the selection pin CS of the A/D converting chip 21, and the A/D converting chip 21 starts operating.

The A/D converting chip 21 receives the sound signal S1, and outputs a digital signal with a duty cycle to the cathode of the diode D0. When the digital signal from the A/D converting chip 21 is a digital high level signal, the diode D0 is turned off. The I/O port P3.0 of the processor 31 receives a voltage of the power source P3V. When the digital signal from the A/D converting chip 21 is a digital low level signal, the diode D0 is turned on. The I/O port P3.0 of the processor 31 receives a digital low level signal. A duty cycle of an input signal received by the I/O port P3.0 of the processor 31 is the same as the duty cycle of the digital signal from the A/D converting chip 21. In this embodiment, each portion of the duty cycle is corresponding to each unit sound decibel (dB). If the maximum value of the duty cycle is 100%, the value of 100% of the duty cycle is corresponding to a sound decibel (dB) of 100 dB. If the minimum value of the duty cycle is 0, the value of 0 of the duty cycle is corresponding to a sound decibel (dB) of 0 dB. Therefore, the processor 31 can determine a certain range of the sound of the surrounding environment of the mobile phone, according to the input signal from the I/O port P3.0 of the processor 31.

When a range of the sound of the surrounding environment is 40 dB-60 dB, the I/O port P3.0 of the processor 31 outputs a volume increasing signal to the volume adjusting port A of the alarm tone unit 200, to control a volume of the alarm tone unit 200 to increase by 15 dB. When sound decibel (dB) of the surrounding environment of the mobile phone is greater than 60 dB, in addition to the volume of the ringing increased by 15 dB, the I/O port P1.4 of the processor 31 outputs a vibration on signal to the vibration on port Son of the alarm tone unit 200, to open a vibration function of the mobile phone. When the sound decibel (dB) of the surrounding environment of the mobile phone is less than 60 dB, the I/O port P1.4 of the processor 31 stops working. The I/O port P1.5 of the processor 31 outputs a vibration off signal to the vibration off port Soff of the alarm tone unit 200, to turn off the vibration function of the mobile phone.

When the range of the sound of the surrounding environment is 20 dB-40 dB, the I/O port P3.1 of the processor 31 outputs a volume decreasing signal to the volume adjusting port A of the alarm tone unit 200, to control the volume of the alarm tone unit 200 to decrease by 5 dB. When the sound decibel (dB) of the surrounding environment of the mobile phone is less than 20 dB, the I/O port P1.7 of the processor 31 outputs a sound off signal to the ringing off port Voff of the alarm tone unit 200. The I/O port P1.4 of the processor 31 starts working, to turn off the alarm tone of the mobile phone, and to open the vibration of the mobile phone. When the sound decibel (dB) of the surrounding environment of the mobile phone is greater than 20 dB, the I/O port P1.6 of the processor 31 outputs a sound open signal to the ringing on port Von of the alarm tone unit 200, to open the ringing of the mobile phone. In the meantime, the I/O port P1.5 of the processor 31 starts operating, and the vibration of the mobile phone is shut off

Therefore, the alarm tone adjustment circuit 100 can change the volume of the alarm tone of the mobile phone, according to the sound of the surrounding environment.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. An alarm tone adjustment circuit comprising:
a sound collection unit configured to collect sound of a surrounding environment;
an analog-digital (A/D) convertor coupled to the sound collection unit, and transforming the collected sound to a digital signal; and
a processing unit coupled to the A/D convertor and an alarm tone unit;
wherein the processing unit determines a decibel range of the digital sound according to a duty cycle; and adjusts a volume of a ring output from the alarm tone unit, or enable/disable the ring output from the alarm tone unit, or enable/disable a vibration output from the alarm tone unit, according to the determined decibel range.

2. The alarm tone adjustment circuit of claim 1, wherein A/D convertor comprises an A/D converting chip and a diode, an input pins of the A/D converting chip is coupled to an output terminal of the sound collection unit to receive the sound of the surrounding environment, an output terminal of the A/D converting chip is coupled to a first power source through a first resistor, a cathode of the diode is coupled to the output terminal of the A/D converting chip, and an anode of the diode is coupled to the processing unit.

3. The alarm tone adjustment circuit of claim 2, wherein the processing unit comprises a processor and a switch, the processor comprises first, second, and third I/O ports; the first I/O port is coupled to the anode of the diode, and is coupled to a second power source through a second resistor, the second I/O port is coupled to a volume adjusting port of the alarm tone unit; the third I/O port is coupled to the switch, and is coupled to the second power source through a third resistor; the processing unit determines the decibel range of the digital signal according to the duty cycle output from the A/D convertor, and outputs a volume control signal to the volume adjusting port of the alarm tone unit according to the determined decibel range, for increasing or decreasing the volume of the ring output by the alarm tone unit; when the switch receives a digital high level signal, the processor starts operating.

4. The alarm tone adjustment circuit of claim 1, wherein the processor further comprises fourth and fifth I/O ports, the fourth I/O port is coupled to a vibration on port of the alarm tone unit, the fifth I/O port is coupled to a vibration off port of the alarm tone unit, the first I/O port controls the fourth I/O port to output a vibration on signal to the vibration on port according to the duty cycle of the digital signal output from the A/D convertor, or controls the fifth I/O port to output a vibration off signal to the vibration on port.

5. The alarm tone adjustment circuit of claim 4, wherein the processor further comprises sixth and seventh I/O ports, the six I/O port is coupled to a ringing on port of the alarm tone unit, the seventh I/O port is coupled to a ringing off port of the alarm tone unit, the first I/O port controls the sixth I/O port output a ringing on signal to the ringing on port according to the duty cycle, or controls the seventh I/O port output a ringing off signal to the ringing off port.

6. The alarm tone adjustment circuit of claim 5, further comprising a switch and buffer unit outputting a switch and buffer signal to the A/D convertor, wherein the switch and buffer unit comprises an electronic switch, a control terminal of the electronic switch is coupled to the third I/O port of the processor, a first terminal of the electronic switch is coupled to the first power source through a fourth resistor, and is coupled to a selection pin of the A/D convertor, and a second terminal of the electronic switch is grounded.

7. The alarm tone adjustment circuit of claim 6, wherein the processor further comprises an eighth I/O port, the eighth I/O port is coupled to the second power source through a fifth resistor, the switch and buffer unit further comprises a buffer, two input terminals of the buffer are coupled to the eighth I/O port of the processor, and an output terminal of the buffer is coupled to a clock pin of the A/D convertor.

8. The alarm tone adjustment circuit of claim 6, wherein the electronic switch is an n-channel metal oxide semiconductor field-effect transistor (MOSFET), the control terminal, the first terminal, and the second terminal of the electronic switch correspond to a gate, a source, and a drain of the MOSFET, respectively.

9. The alarm tone adjustment circuit of claim 7, wherein the processor is a singlechip.

10. An electronic device, comprising: an alarm tone adjustment circuit and an alarm tone unit, the alarm tone adjustment circuit comprising:
a sound collection unit configured to collect sound of a surrounding environment;
an analog-digital (A/D) convertor coupled to the sound collection unit, and converting the collected sound to a digital signal; and
a processing unit coupled to the A/D convertor and an alarm tone unit;
wherein the processing unit determines a decibel range of the digital signal according to a duty cycle; and adjusts a volume of a ring output from the alarm tone unit, or enable/disable the ring output from the alarm tone unit, or enable/disable a vibration output from the alarm tone unit, according to the determined decibel range.
